(19) United States
(12) Patent Application Publication
(10) Pub. No.: US 2020/0018514 A1
(43) Pub. Date: Jan. 16, 2020

(54) SYSTEMS AND METHODS FOR TEMPORARY MOUNTING OF A HOUSING COVER

(71) Applicant: Johnson Controls Technology Company, Auburn Hills, MI (US)

(72) Inventors: Peggy D. Howe, Milwaukee, WI (US); Gary W. Gavin, Franklin, WI (US); James Mertz, Wind Lake, WI (US)

(73) Assignee: Johnson Controls Technology Company, Auburn Hills, MI (US)

(21) Appl. No.: 16/244,550

(22) Filed: Jan. 10, 2019

Related U.S. Application Data
(60) Provisional application No. 62/695,908, filed on Jul. 10, 2018.

(51) Int. Cl. F24F 11/89; H05K 5/03; F24F 11/70; H05K 5/02; F24F 11/52; H05K 5/00

(52) U.S. Cl. CPC F24F 11/89; H05K 5/03; F24F 11/70; H05K 5/0247; F24F 11/52; H05K 5/0017; H05K 5/0226

(57) ABSTRACT

A terminal device housing includes a backplate and a front cover. The backplate is attachable to a mounting surface. A display is supported by the front cover. The backplate and front cover are formed with installation engagement elements that allow the front cover to be releasably attached to the backplate as the backplate is wired and mounted to the mounting surface. Following wiring and mounting of the backplate, the front cover is detached from the mounted backplate. Engagement structures formed on the backplate and front cover allow the front cover to be attached to the mounted rear cover to define a terminal device housing.

### CROSS-REFERENCE TO RELATED APPLICATION

This application claims the benefit of and priority to U.S. Provisional Patent Application No. 62/695,908 filed Jul. 10, 2018, the entire disclosure of which is incorporated by reference herein.

### BACKGROUND OF THE INVENTION

The present disclosure relates to terminal devices, and more particularly, to a terminal device housing assembly configured to facilitate installation of a terminal device to a desired mounting surface. Mounted terminal devices are generally defined by a housing comprising a front half and a rear half. When assembled, the front half and the rear half define a housing interior within which various components of the terminal device are contained. Supported by the front half of the housing is a display which allows a user to monitor, control and/or otherwise engage with the functioning of the terminal device.

Installation of terminal devices to a desired mounting surface typically involves separating the front half and the rear half of the housing so that wiring (from a heating and/or cooling system, e.g.) extending from the mounting surface may be connected to control elements supported by the rear half of the housing and so that the rear half of the housing can be mounted to the mounting surface.

During the mounting of the rear half of the terminal device, a user will typically have to set aside the front half of the housing. Given that sensitive control elements are supported by a rear surface of the front half and the front surface of the front half of the housing supports a delicate display, the user risks damaging the front half of the housing if the front half is not carefully placed on an appropriate surface while the user mounts and wires the rear half of the housing. Additionally, as often times a user may be installing several different terminal devices within a single location at the same time, the user must be careful to remember where the front half of the housing has been placed so as to avoid the user mistaking the corresponding front half of the mounted rear half with a front half of a different terminal device which is also being installed by the user.

Some terminal device housings have attempted to resolve these issues by hingedly attaching the bottom ends of the front half and rear half. In such hinged housing arrangements, when the rear half of the housing is being mounted, the front half of the housing hangs upside down from the bottom of the rear half, with the rear surface of the front half facing the user and the supported display being positioned opposite the surface to which the terminal device is being mounted.

Although such hinged attachment of the front and rear halves of a housing during installation of a terminal device may reduce the risk of the front half being misplaced during mounting of the rear half to a mounting surface, such hinged housing arrangements poses a number of undesirable issues. In particular, because the delicate display supported by the front half of such housing arrangements is positioned against the surface during mounting of the rear half, the user risks damaging the display as the user mounts and wires the rear half of the housing. Additionally, manufacturing a terminal device having such hingedly attached front and rear halves is considerably more expensive than the manufacture of a terminal device defined by discrete, separate front and rear halves. Also, in the event that such a hinged terminal device becomes damages, the entire terminal device will have to be replaced, even if the damage is localized to only one of the front half or rear half of the housing. Accordingly, it would be desirable to provide a terminal device housing arrangement which does not raise such issues, while still allowing the user to releasably secure the front half to the rear half of the housing during mounting of the rear half to a mounting surface.

### SUMMARY

According to one implementation of the present disclosure, a thermostat includes a front cover and a back cover. The front cover includes a front surface, a rear surface, a plurality of engagement structures, and one or more installation engagement elements. The back cover includes a front surface, a rear surface, a plurality of engagement structures, and one or more installation engagement elements. The engagement elements of the back cover are configured to engage the engagement structures of the front cover to define a housing. The installation engagement elements of the back cover are configured to engage the installation engagement elements of the front cover to define a mounting assembly configuration.

In some embodiments, in the mounting assembly configuration, the front cover extends at a location below the lower portion of the back cover. In some embodiments, in the mounting assembly configuration, the front surface of the front cover and the front surface of the back cover each face the same direction.

In some embodiments, the plurality of installation engagement elements of the front cover are defined by a plurality of arm elements each having a hooked free end extending rearwardly from the rear surface of the front cover. In some embodiments, the plurality of installation engagement elements of the rear cover comprises a plurality of ledges. The hooked free end of each arm element is configured to rest atop an upper surface of the ledge and engage a rear surface of the ledge.

In some embodiments, the plurality of installation engagement elements of the back cover further comprises a plurality catches. The catches extend rearwards relative to the rear surfaces of the ledges. The hooked free ends of the arm elements are configured to extend into the catches when the arm elements are engaged with the ledges.

In some embodiments, the lower portion of the front surface of the back cover is defined by a bottom wall. The catches are defined by openings extending through the bottom wall and the ledges extend upwards from an upper surface of the bottom wall.

In some embodiments, a display is supported by the front surface of the front cover. In some embodiments, at least one of the installation engagement elements of the back cover also defines one of the engagement structures of the back cover.

One implementation of the present disclosure is a thermostat cover. The thermostat cover includes a substantially planar front surface and a display supported by the front surface. The thermostat cover also includes a substantially planar rear surface and one or more display control elements supported by the rear surface. The one or more display control elements extend rearwards from and in a direction generally perpendicular to the rear planar surface by a first distance. A plurality of support struts are formed about the rear surface. Each of the support struts extends rearwards from and in a direction generally perpendicular to the rear planar surface by a second distance. The second distance is greater than the first distance. An attachment structure is formed on and extends from a rear end of at least one of the support struts.

In some embodiments, the attachment structures are defined by a hook structure. In some embodiments, the attachment structures are defined by a rounded structure. In some embodiments, one or more attachment elements are formed about the rear surface. The one or more attachment elements are configured to engage corresponding structures on a backplate to form a thermostat housing. In some embodiments, the one or more display control elements include a display cable or ribbon.

One implementation of the present disclosure is a method of installing a thermostat. An upper portion of a front cover is releasably suspended to a lower portion of a rear cover to define a mounting assembly. The rear cover is attached to a mounting surface while the front cover and rear cover define the mounting assembly. The mounting assembly is disassembled by removing the front cover from the rear cover. The rear cover remains attached to the mounting surface following disassembly of the mounting assembly. The front cover is attached to the mounted rear cover to define a housing structure.

In some embodiments, an outer periphery of the rear cover and an outer periphery of the front cover extend generally concentrically relative to one another when the front cover and rear cover define the housing structure.

In some embodiments, one or more installation engagement elements are formed about the upper portion of the front cover. The one or more installation engagement elements of the front cover are configured to engage one or more installation engagement elements formed about the lower portion of the rear cover to releasably hang the front cover from the rear cover.

In some embodiments, following disassembly of the mounting assembly, the front cover and rear cover define two discrete structures that are entirely detached from one another.

In some embodiments, a display having a rear surface and a front surface is supported by the front cover. The rear surface of the display is positioned opposite the mounting surface while the mounting assembly is attached to the mounting surface. In some embodiments, subsequent to attaching the rear cover to the mounting surface and prior to disassembling the mounting assembly, a display cable connected to the display is attached to a thermostat control element supported by the rear cover to determine whether the thermostat control element is capable of controlling the display to display one or more images.

Those skilled in the art will appreciate that the summary is illustrative only and is not intended to be in any way limiting. Other aspects, inventive features, and advantages of the devices and/or processes described herein, as defined solely by the claims, will become apparent in the detailed description set forth herein and taken in conjunction with the accompanying drawings.

### BRIEF DESCRIPTION OF THE DRAWINGS

Exemplary embodiments will become more fully understood from the following detailed description, taken in conjunction with the accompanying drawings, wherein like reference numerals refer to like elements, and:

FIG. 1A illustrates a front perspective view of an assembled, fully installed terminal device mounted to a surface, according to an exemplary embodiment.

FIG. 1B illustrates a side view of an assembled, fully installed terminal device mounted to a surface, according to an exemplary embodiment.

FIG. 2A illustrates a front perspective view of a backplate of a terminal device, according to an exemplary embodiment.

FIG. 2B illustrates a rear perspective view of a backplate of a terminal device, according to an exemplary embodiment.

FIG. 2C illustrates a side perspective view of a backplate of a terminal device, according to an exemplary embodiment.

FIG. 2D illustrates a top perspective view of a backplate of a terminal device, according to an exemplary embodiment.

FIG. 3A illustrates a side perspective view of a front cover of a terminal device, according to an exemplary embodiment.

FIG. 3B illustrates a rear perspective view of a front cover of a terminal device, according to an exemplary embodiment.

FIG. 4A illustrates a top perspective view of a temporary mounting assembly configuration of a terminal device, according to an exemplary embodiment.

FIG. 4B illustrates a rear perspective view of a temporary mounting assembly configuration of a terminal device, according to an exemplary embodiment.

FIG. 4C illustrates a front perspective view of a temporary mounting assembly configuration of a terminal device, according to an exemplary embodiment.

FIG. 4D illustrates a detailed, cross-sectional side view of the circled portion of the terminal device of FIG. 4C, according to an exemplary embodiment.

### DETAILED DESCRIPTION

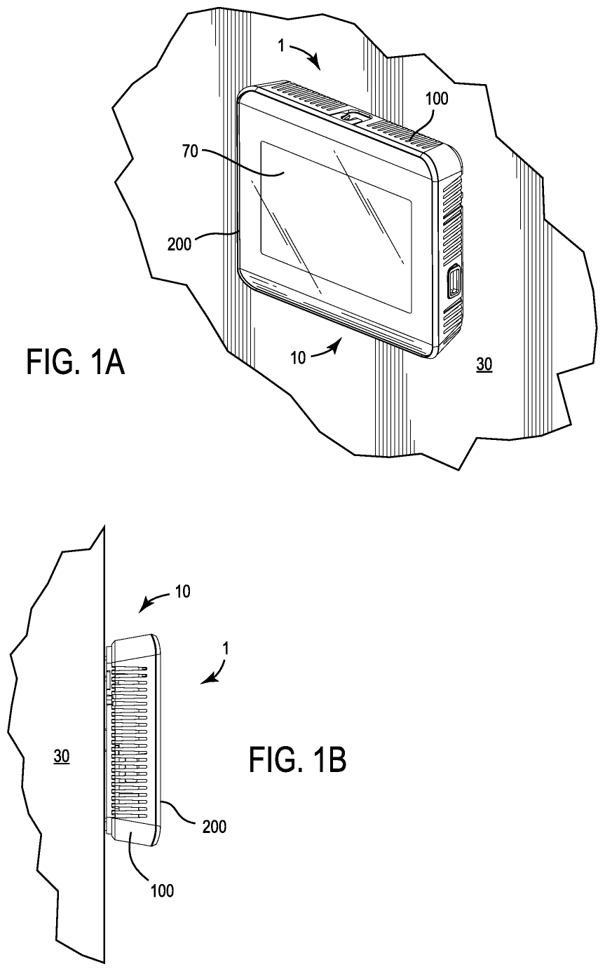

Referring to FIGS. 1A and 1B, an assembled, installed terminal device 1 mounted to a wall 30 is shown according to one embodiment. In general, thermostat 1 includes a housing 10 within which a control system 50 and a user interface, such as, e.g., a touchscreen display 70, is supported. As will be understood, although the terminal device 1 is shown in FIGS. 1A and 1B as being mounted to a wall 30, according to other embodiments, the terminal device 1 may be mounted to any number of different types of mounting surfaces and/or structures. The terminal device 1 may be configured to be mounted to a mounting surface in any desired arrangement or configuration, including a vertically mounting arrangement such as illustrated in FIGS. 1A and 1B.

According to various embodiments, the terminal device 1 may comprise any number of different electronic or non-electronic devices which include a rear backplate portion configured to attach the terminal device 1 to a mounting surface and a front cover portion configured to attach to the backplate portion subsequent to the mounting of the backplate portion to the mounting surface. Non-limiting examples of various terminal devices 1 include: thermostat controllers, communication system controllers, access point controllers, switch plates, actuators, proximity sensors, smoke detectors, CO2 detectors, routers, relays, entertainment systems, fire panels, security systems, display panels, lighting systems, fire control systems, control systems cabinets, sensors, transmitters, signal hubs, intercoms, communications devices, interactive controls, general building management or facilities management devices, etc. It is to be understood that that shape and size of the terminal device 1 illustrated in FIGS. 1A and 1B is exemplary, such that the shape and size of the terminal device 1 may be varied as desired, depending on the type of and/or nature of use of the terminal device 1.

In general, terminal device 1 is defined by a housing 10 within and/or on which any number of different components may optionally be stored and/or supported. For example, in some embodiments, housing 10 may be configured to support a control system 50. In some embodiments, the housing 10 may be configured to additionally, or alternatively, support or otherwise house a user interface (e.g. such as display 70) via which a user may operate, monitor, input information into, and/or otherwise engage with the terminal device 1.

If included, control system 50 may be defined by any number of, and any combination of, different components as desired, depending on variables such as, e.g., the type of and/or nature of use of the terminal device 1, the types of external systems with which the terminal device 1 may be configured to be used, etc. Non-limiting examples of various control system 50 components include: terminal blocks, circuit boards, memory storage, microcontrollers, processors, sensors, light emitting diodes, power sources, receivers, transmitters, transceivers, gears, springs, drive systems, motors, etc.

As noted above, according to various embodiments, such as, e.g. illustrated in FIGS. 1A and 1B, the optionally included user interface may include a display 70, which is some embodiments may comprise a touchscreen display. In other embodiments, the user interface may include any other number of different structures allowing a user to monitor, control, or otherwise engage with the terminal device 1 via direct, physical and/or remote (e.g. wireless) interaction, including: displays, screens, windows, physical control buttons; a turn-wheel having graduated markings printed thereon; a sliding detent, etc.

As shown in FIGS. 1A and 1B, the terminal device housing 10 is comprised of a backplate 100 and a front cover 200 that are configured to be attached to one another to define the interconnected, assembled housing 10 structure illustrated in FIGS. 1A and 1B. The backplate 100 and front cover 200 may be formed of any number of, and any desired combination of, materials, such as, e.g., metal, plastic, etc.

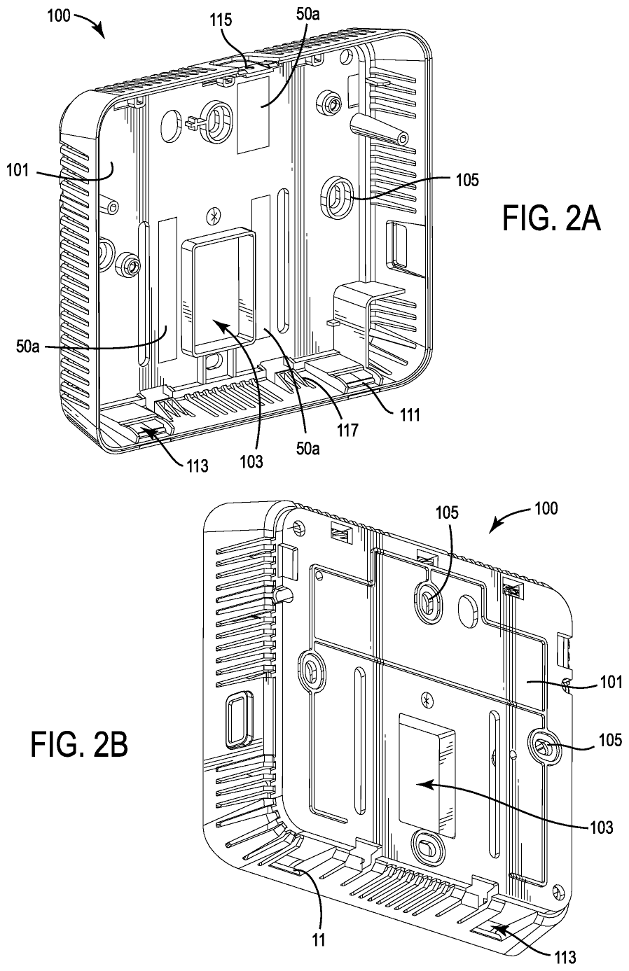

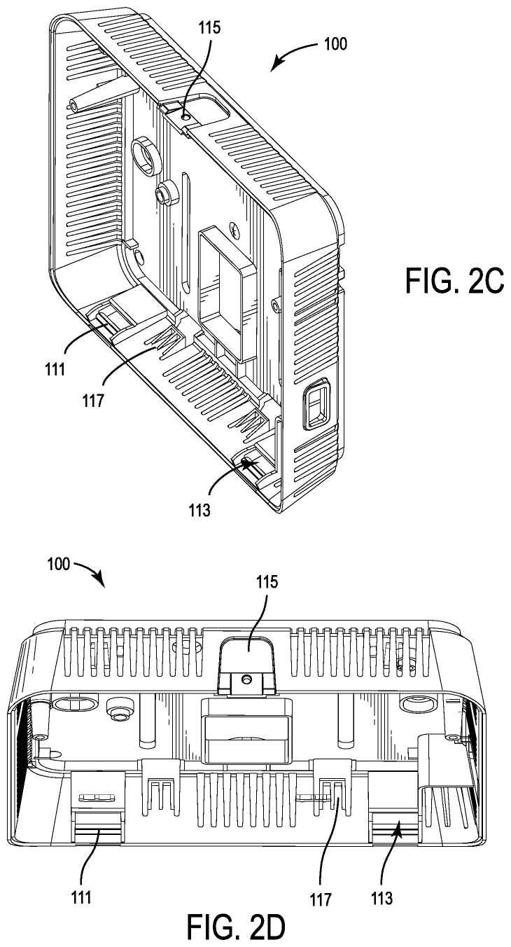

As shown in FIGS. 2A-2D, according to various embodiments, backplate 100 is defined by a generally planar back surface 101. A sidewall 107 extends about a portion of the back surface 101. The back surface 101 is configured to lie against the desired mounting surface to which the terminal device 1 is to be attached. Provided along the back surface 101 are one or more attachment elements configured to allow the terminal device 1 to be mounted to a desired surface. As illustrated by FIGS. 2A-2D, according to various embodiments, the one or more attachment elements may comprise one or more through-holes 105 through which one or more screws, surface anchors, nails, etc. are configured to pass to attach the backplate 100 to a mounting surface. However, according to other embodiments, attachment element may comprise any other number of, or combination of, structures that allow the backplate 100 to be attached to a desired mounting surface, and may be arranged, spaced, or otherwise positioned in any number of desired configurations.

As representatively illustrated by blocks 50a in FIG. 2A, attached along and supported by the back surface 101 of backplate 100 are one or more components 50a. In some embodiments, components 50a may define or form a portion of control system 50. As will be understood, the one or more components 50a that may be supported by the backplate 100 may include any number of different components, such as, e.g., elements as described above with reference to components of control system 50. Components 50a may be arranged, spaced, or otherwise positioned in any number of desired configurations about backplate 100.

In some embodiments, the terminal device 1 may define a self-contained system capable of operating entirely independent from any external system. In other embodiments, the terminal device 1 may be configured to connect to any number of, or any combination of, external systems such as, but not limited to, power supplies, heating and/or cooling systems, irrigation systems, security systems, fire systems, communications systems, building/facilities management systems, entertainment systems, electronic systems, etc. In some such embodiments, the terminal device 1 may be configured to connect to the external system wirelessly. In other embodiments, the terminal device 1 may alternatively (or additionally) may be configured to connect to one or more elements of the external system via a wired or other physical connection.

As illustrated in FIGS. 2A-2D, in some embodiments in which a component 50a, 50b of one or both of the backplate 100 or front cover 200 is configured to attach, connect, or otherwise physically engage an element of an external system, one or more openings 103 may be formed in the backplate 100 via which the one or more elements of the external system may be configured to pass so as to allow the elements to engage components 50a and/or components 50b. Although not shown, it is to be understood that openings 103 may alternatively, or additionally, optionally be provided on the front cover 200, with the number, structure, sizing, spacing, arrangement, etc. of the openings 103 in back plate 100 and/or front cover 200 being varied based on variables such as, e.g. the type and configuration of the external system component to which the terminal device is connected, the nature and type of interaction between the terminal device 1 and external system, etc.

For example, in various embodiments, the terminal device 1 may comprise a thermostat controller, with opening 103 in backplate 100 being configured to allow wiring from, e.g. a heating and/or cooling system, to be connected to thermostat components stored within the housing 10. In another example, according to other embodiments, the terminal device 1 may comprise a damper actuator, with an opening 103 formed in the backplate 100 and a corresponding opening (not shown) formed in front cover 200 being configured to allow the actuator to engage a damper shaft configured to be controlled by the actuator.

Provided along the inner surface of the bottom portion of the sidewall 107 of the backplate 100 are one or more installation engagement elements, such as, e.g. lip-defined ledges 111 and catches 113. As will be described in more detail below, these installation engagement elements of the backplate 100 are configured to engage with corresponding installation engagement elements, such as, e.g. hooked arms 201, formed about an upper portion of the front cover 200 to facilitate installation of the terminal device 1 to a desired mounting structure, such as, e.g., wall 30.

As noted above, in a final assembled configuration (such as, e.g., illustrated in FIGS. 1A and 1B), the backplate 100 is configured to be attached to front cover 200 to define a housing 10 structure. Accordingly, as will be understood, provided about any number of desired locations about the backplate 100 may be any number of different engagement structures configured to interact with corresponding engagement structures formed about the front cover 200 to attach the backplate 100 to the front cover 200, which may be shaped, sized and arranged in any number of different configurations as desired.

According to some embodiments, following the completion of the installation of the backplate 100 of the terminal device 1 to a desired mounting surface, the installation engagement elements (such as, e.g. ledges 111 and/or catches 113) may be configured to serve as engagement structures configured to engage corresponding engagement structures formed about a lower portion of the front cover 200 to finalize installation and assembly of the terminal device 1. For example, in some embodiments, following the installation of the backplate 100 to a wall 30, the catches 113 formed about the bottom portion of the sidewall 107 may be configured to engage corresponding detent arm 211 engagement structures formed about a lower portion of the front cover 200.

Optionally provided along the backplate 100 may be one or more securement structures 115 configured to engage corresponding securement structures 209 formed on the front cover 200. Following the initial attachment of the backplate 100 and front cover 200 via engagement structures to define housing 10, engagement of the optionally provided securement structures 115, 209 formed on the backplate 100 and front cover 200, respectively, may be configured to reinforce and ensure the attachment of the backplate 100 and front cover 200. In some embodiments, in addition to being use to ensure a stable attachment between the engagement structures of the backplate 100 and front cover 200, the attachment of the securement structures 209, 115 may be further configured to provide a secure, locked attachment of the front cover 200 and backplate 100 to ensure that the terminal device 1 is not opened and tampered with following installation.

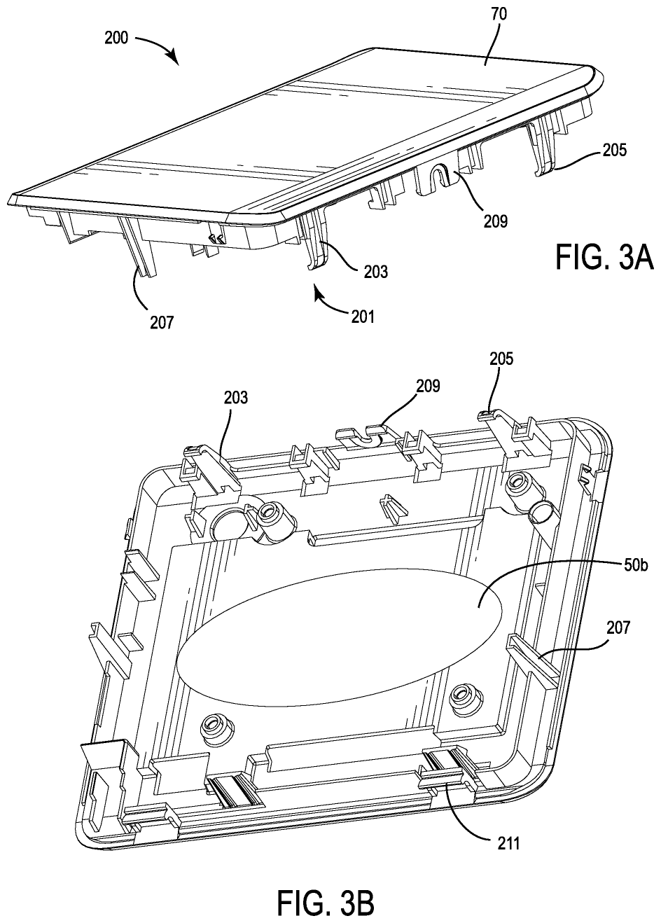

Referring to FIGS. 3A and 3B, a front cover 200 according to one embodiment in shown. As illustrated by the embodiment of FIGS. 3A and 3B, according to various embodiments, an outer, front surface of the front cover 200 may define an interior space within which a display 70 is supported. In some embodiments, one or more components 50b (as representatively illustrated by block 50b) may optionally be supported by a rear surface of the front cover 200, which may function independent of and/or in conjunction with any optionally provided components 50b supported by the rear cover. In some embodiments, components 50b form a part of control system 50 of the terminal device 1. As will be understood, the one or more components 50b that may be supported by the front cover 200 may include any number of different components, such as, e.g., a ribbon cable for display 70 or other elements as described above with reference to control system 50. Components 50b may be arranged, spaced, or otherwise positioned in any number of desired configurations about front cover 200.

As discussed above, formed about any number of different locations of the front cover 200 are any number of, and any combination of, engagement structures configured to interact with corresponding engagement structures formed on the backplate 100 to assemble terminal device 1. As also noted above, optionally provided along front cover 200 may also be one or more securement structures 209 configured to engage a corresponding securement structure 115 of the backplate 100 to provide any desired degree of additional reinforcement of the attachment between the backplate 100 and front cover 200.

Referring to FIGS. 3A and 3B, extending rewards from the rear surface of the front cover 200 are a plurality of support elements, such as legs 207 and hooked arms 201 configured to allow a user to place the front cover 200 on a flat surface without risking damage to the display 70 or components 50b of the control system 50 supported by the front cover 200. In particular, as illustrated in FIG. 3A, legs 207 and hooked arms 201 each have heights that are greater than the height of any of the components 50b of the control system 50 that are supported by the rear surface of the front cover 200. In such a manner, the legs 207 and hooked arms 201 are configured to allow the front cover 200 to be set down on a flat surface with the front surface of the front cover 200 facing upwards (so as to, e.g., avoid scratching or otherwise damaging the display 70 or other front surface of the front cover 200), with the legs 207 and hooked arms 201 elevating the rear surface of the front cover 200 by an amount sufficient to prevent any delicate components 50b supported by the front cover 200 from coming into contact with the flat surface. As will be understood, according to various embodiments the legs 207 and hooked arms 201 may also be configured so as to be equal to or less than the height of the sidewall 107 of the backplate 100, so as to allow the front cover 200 to be attached to the backplate 100.

During installation of the terminal device 1, the backplate 100 and front cover 200 are separated from the final housing 10 structure (such as, e.g., shown in FIGS. 1A and 1B) so that the backplate 100 may be secured to the mounting surface, and—for embodiments in which the terminal device is physically connected to an element of an external systems—so that the external system element may be passed into to the housing 10 so as to be able to engage as needed with the components 50a and/or 50b of the terminal device 1. For example, in embodiments in which terminal device 1 comprises a thermostat controller, wiring from a heating and/or cooling device may be passed through opening 103 and connected to the appropriate components 50a or 50b of a control system 50 comprising a thermostat as required for operation of the terminal device 1.

According to some embodiments, during these installation steps, the user may utilize the legs 207 and hooked arms 201 of the front cover 200 to safely rest the front cover 200 on a flat surface as the user in mounting the backplate 100 to the mounting surface. However, in some situations, a user may not always have a nearby flat surface onto which the front cover 200 may be conveniently placed. Also, in some situations, even if a flat surface is available, it may not be desired to rest the front cover 200 on the flat surface as the backplate 100 is being mounted. For example, in a situation in which multiple terminal devices having differing control components are being installed at the same location and the same time, a user may prefer not to place the front cover 200 on the flat surface, to avoid misplacing or mistaking the front cover of another terminal device with the front cover 200 that is to be attached to the backplate 100

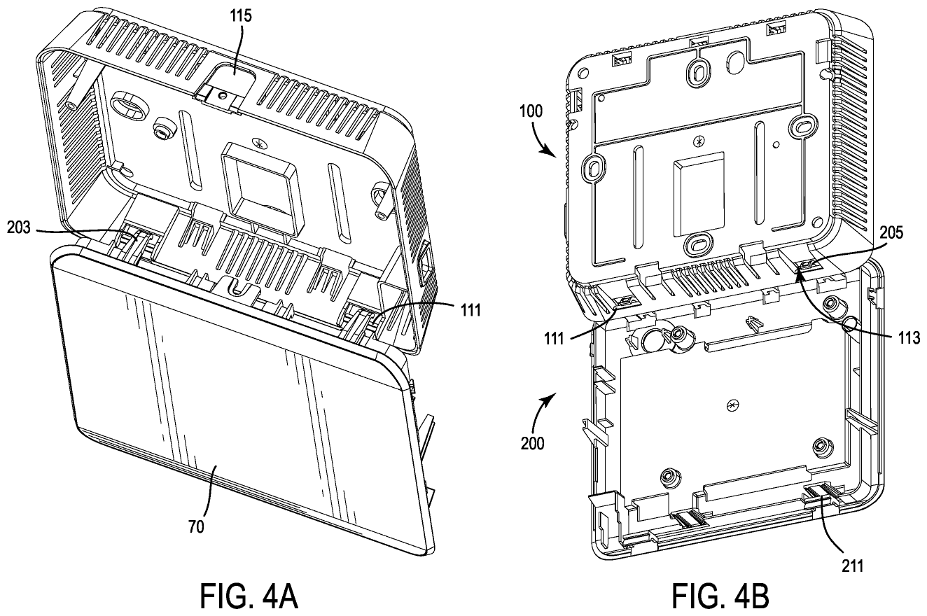

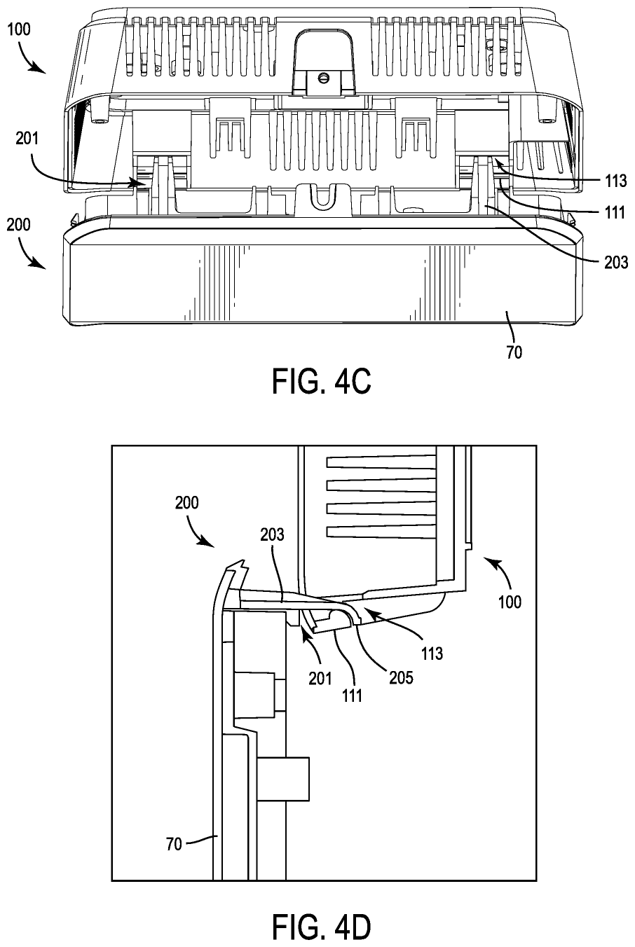

Accordingly, in addition to being configured to allow the front cover 200 to be securely placed on a flat surface, the hooked arms 201 of the front cover 200 also act as installation engagement elements that are configured to interact with the installation engagement elements (e.g., ledges 111 and catches 113) of the backplate 100 to allow for an improved method of installation of the terminal device 1 to a wall 30. In particular, as illustrated in FIGS. 4A-4D, the hooks 205 formed at the rear of the arm portions 203 of the hooked arms 201 on the front cover 200 are configured to be rested atop ledges 111 to engage with catches 113 to securely, but releasably, hang the front cover 200 from the backplate 100. As illustrated in FIGS. 4A-4D, the interaction of the ledge 111 and catch 113 installation engagement elements of the backplate 100 with the hooked arm 201 installation elements of the front cover 200 is configured to allow the backplate 100 and front cover 200 to form an initial mounting assembly defined by a single unit backplate 100/front cover 200 structure during the mounting of the backplate 100 to a mounting surface, such as, e.g. wall 30. By allowing the user to attach backplate 100 and front cover 200 using installation engagement elements to form a temporary, single combined backplate 100/front cover 200 unit, the user need not spend time finding an appropriate flat surface on which to place the front cover 200 during mounting of the backplate 100 or risk the possibility of the front cover 200 being lost or unable to be easily identified amongst other front covers, thereby facilitating the installation of the terminal device 1.

In addition to facilitating installation by allowing the backplate 100 and front cover 200 to be handled as a single unit during mounting of the backplate 100 to a wall 30, the configuration of the single unit defined as a result of the attachment of the backplate 100 and front cover (as illustrated, e.g., in FIGS. 4A-4D) such that the front of the front cover 200 faces away from the wall 30 during mounting of the backplate 100 to the wall 30 also helps shield the delicate components 50b of the control system 50 supported on the rear surface of the front cover 200, thereby minimizing the risk of accidental user contact or other disruption of these delicate components 50b. Also, according to some embodiments, the ability of the user to view the display 70 supported by the front cover 200 as the user is installing the backplate 100 may provide the user with an easy and convenient opportunity to test the operation of the terminal device 1 prior to the final assembly of the front cover 200 to define housing 10 (such as, e.g. shown in FIGS. 1A and 1B), allowing the user to troubleshoot and debug any issues with any or all of any or all optionally included components 50a, 50b without having to first disassemble the housing 10.

Because the installation engagement elements 111, 113 of the backplate 100 are formed as discrete, separate elements from the hooked arm 201 installation engagement elements of the front cover 200, the backplate 100 and front cover 200 may be manufactured as separate, discrete components, thereby minimizing costs (as compared to, e.g. costs that would be associated with manufacturing a backplate 100 and front cover 200 attached to one another via integrally formed installation engagement elements such as, e.g., a hinge structure).

According to an exemplary embodiment of a method for installing terminal device 1, prior to mounting the backplate 100, the user may attach the upper end of the front cover 200 to the lower end of the backplate 100 by engaging the hooked arm 201 installation engagement elements of the front cover with the ledge 111 and catch 113 installation engagement elements of the backplate 100 in a manner as illustrated in FIGS. 4C and 4D to form a single unit initial mounting assembly as illustrated, e.g. in FIGS. 4A and 4B. If needed, any external system elements (e.g. wiring) configured to be connected to optionally provided components 50a, 50b supported within the housing 10 may be inserted through opening 103 in backplate, and the backplate 100 may be secured to the mounting surface via one or more screws or other structures using the through-holes 105 defined in backplate 100. Following mounting of the backplate, if not already completed, the user may finalize any remaining engagements of external system elements to components 50a, 50b, as well as the connection of components 50b supported by the front cover 200 to the components 50a supported by the backplate 100. If needed, external system elements may also be passed through openings 103 in front cover (not shown) and be engaged as needed to components 50a and 50b.

As noted above, according to some embodiments, while the backplate 100 and front cover 200 are still connected as a single unit mounting assembly (such as, e.g., illustrated in FIGS. 4A-4D), the user may take advantage of the ability to both view the display 70 and have access to the attachment of any external system elements to components 50a and/or 50b, and/or connections between components 50a and 50b to verify the functioning of the terminal device 1 and troubleshoot any potential issues prior to disengaging the installation engagement elements 111, 113, and 201 and engaging the engagement structures of the backplate 100 and front cover 200 to define housing 10.

Once the backplate 100 has been attached to the wall 30 and any needed engagement of external system elements (e.g. wiring) to components 50a and/or 50b and/or connection of components 50a to components 50b, the user may disengage the ledge 111 and catch 113 installation engagement elements of the backplate 100 from the hooked arm 201 installation engagement elements of the front cover 200 to separate the backplate 100 and front cover 200 and reattach the front cover 200 to the mounted backplate 100 via engagement structures to form the final, assembled housing 10 arrangement of the backplate 100 and front cover 200 (such as, e.g., illustrated in FIG. 1). If provided, once the backplate 100 and front cover 200 have been attached using engagement structures, the attachment of the housing 10 may be reinforced by engaging the securement structures 115, 209 of the backplate 100 and front cover 200, respectively.

As will be understood, although the installation engagement elements have been described and illustrated as being defined by catches 113, ledges 111, and hooked arms 201, it is to be understood that, according to other embodiments, the installation engagement elements of the backplate 100 and/or front cover 200 may comprise any other number of different structures and arrangement of structures that would allow for the secure, releasably hanging attachment of the front cover 200 to the backplate 100 to define the single unit initial mounting assembly. For example, according to some embodiments, the catches 113 and ledges 111 described as being formed on backplate 100 may instead be formed on front cover 200, with the hooked arms 201 of the front cover 200 being instead formed as part of the backplate 100. In other embodiments, the installation engagement elements may be defined by ball and socket structures, in which arms supporting ball-like end structures formed on one of the front cover 200 and backplate 100 are configured to be supported within corresponding socket-like indentations or openings formed in the other of the front cover 200 and backplate 100. In yet other embodiments, the installation engagement elements may comprise a tongue-like structure(s) formed on the backplate 100 or front cover 200 that is configured to be slid into a corresponding groove structure formed on the other of the backplate and front cover 200.

The construction and arrangement of the systems and methods as shown in the various exemplary embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.). For example, the position of elements may be reversed or otherwise varied and the nature or number of discrete elements or positions may be altered or varied. Accordingly, all such modifications are intended to be included within the scope of the present disclosure. References herein to the positions of elements (e.g., “top,” “bottom,” “above,” “below,” “upper”, “lower”, etc.) are merely used to describe the orientation of various elements in the FIGURES. It should be noted that the orientation of various elements may differ according to other exemplary embodiments, and that such variations are intended to be encompassed by the present disclosure.

The term “coupled,” as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. Such members may be coupled mechanically, electrically, and/or fluidly. The order or sequence of any process or method steps may be varied or re-sequenced according to alternative embodiments. Other substitutions, modifications, changes, and omissions may be made in the design, operating conditions and arrangement of the exemplary embodiments without departing from the scope of the present disclosure.

We claim:

1. A terminal device comprising:
a front cover comprising:
a front surface;
a rear surface; and
one or more front cover installation engagement elements formed about an upper portion of the rear surface of the front cover; and
a back cover comprising:
a front surface;
a rear surface; and
one or more back cover installation engagement elements formed about a lower portion of the front surface of the back cover;
wherein the one or more front cover installation engagement elements are configured to releasably engage the one or more back cover installation engagement elements to define a mounting assembly configuration.

2. The terminal device of claim 1, wherein, in the mounting assembly configuration, the front cover extends at a location below a lowermost portion of the back cover.

3. The terminal device of claim 2, wherein, in the mounting assembly configuration, the front surface of the front cover and the front surface of the back cover each face the same direction.

4. The terminal device of claim 3, wherein the plurality of front cover installation engagement elements are defined by a plurality of arm elements each having a hooked free end extending rearwardly from the rear surface of the front cover.

5. The terminal device of claim 4, wherein the plurality of back cover installation engagement elements comprise a plurality of ledges, the hooked free end of each front cover arm element being configured to rest atop an upper surface of a back cover ledge and engage a rear surface of the ledge.

6. The terminal device of claim 5, wherein the plurality of back cover installation engagement elements further comprise a plurality catches, the catches extending rearwards relative to the rear surfaces of the ledges, wherein the hooked free ends of the arm elements are configured to extend into the catches when the arm elements are engaged with the ledges.

7. The terminal device of claim 6, the lower portion of the front surface of the back cover being defined by a bottom wall, wherein the catches are defined by openings extending through the bottom wall and the ledges extend upwards from an upper surface of the bottom wall.

8. The terminal device of claim 1, further comprising a plurality of front cover engagement structures formed about the rear surface of the front cover and a plurality of corresponding back cover engagement structures formed about the front surface of the back cover, wherein the back cover engagement structures are configured to engage the front cover engagement structures to define a housing assembly configuration.

9. The terminal device of claim 8, wherein at least one of the back cover installation engagement elements also defines one of the back cover engagement structures.

10. A terminal device cover comprising:
a substantially planar front surface;
a substantially planar rear surface;
one or more electronic components supported by the rear surface, wherein the one or more electronic components extend rearwards from and in a direction generally perpendicular to the planar rear surface by a first distance;
a plurality of support struts formed about the rear surface, wherein each of the support struts extend rearwards from and in a direction generally perpendicular to the rear planar surface by a second distance, the second distance being greater than the first distance, and
one or more attachment structures, each of the one or more attachment structures being formed on and extending from a rear end of a support strut.

11. The terminal device cover of claim 10, wherein the attachment structures are defined by a hook structure.

12. The terminal device cover of claim 10, wherein the attachment structures are defined by a rounded structure.

13. The terminal device cover of claim 10, further comprising one or more attachment elements formed about the rear surface, the one or more attachment elements being configured to engage corresponding structures on a backplate to form a terminal device housing.

14. A method of installing a terminal device comprising:
releasably suspending an upper portion of a front cover to a lower portion of a rear cover to define a mounting assembly;
attaching the rear cover to a mounting surface;
disassembling the mounting assembly by removing the front cover from the rear cover, the rear cover remaining attached to the mounting surface following disassembly of the mounting assembly; and
attaching the front cover to the mounted rear cover to define a housing structure.

15. The method of claim 14, wherein the front cover and rear cover define the mounting assembly as the rear cover is attached to the mounting surface.

16. The method of claim 14, wherein the rear cover is attached to the mounting surface prior to the front cover being attached to the rear cover to define the mounting assembly.

17. The method of claim 14, wherein an outer periphery of the rear cover and an outer periphery of the front cover extend generally concentrically relative to one another when the front cover and rear cover define the housing structure.

18. The method of claim 14, wherein one or more installation engagement elements are formed about the upper portion of the front cover, the one or more installation engagement elements of the front cover being configured to engage one or more installation engagement elements formed about the lower portion of the rear cover to releasably suspend the front cover from the rear cover.

19. The method of claim 14, wherein following disassembly of the mounting assembly, the front cover and rear cover define two discrete structures that are entirely detached from one another.

20. The method of claim 14, wherein a display having a rear surface and a front surface is supported by the front cover, the rear surface of the display being positioned opposite the mounting surface while the mounting assembly is attached to the mounting surface;
further wherein, subsequent to attaching the rear cover to the mounting surface and prior to disassembling the mounting assembly, a display cable connected to the display is attached to a terminal device control element supported by the rear cover to determine whether the terminal device control element is capable of controlling the display to display one or more images.
